(19) United States
(12) Patent Application Publication
(10) Pub. No.: US 2003/0141565 A1
(43) Pub. Date: Jul. 31, 2003

(54) Diode

(76) Inventors: Fumihiko Hirose, Yokohama (JP); Yutaka Souda, Toyonaka (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/055,975

(22) Filed: Jan. 28, 2002

(51) Int. Cl. H01L 31/075; H01L 31/105; H01L 31/117

(52) U.S. Cl. 257/458

(57) ABSTRACT

A diode of the present invention has a Si substrate, a Si film of a first conductivity type laminated on this Si substrate, and a SiGe film of a second conductivity type laminated on this first conductivity type Si film.

### BACKGROUND OF THE INVENTION

1. Field of the Invention

The present invention relates to a diode having high-speed backward recovery characteristics.

2. Description of the Related Art

There has conventionally been widely utilized a high-speed operational diode in circuits of power electronics for the purpose of absorbing the surge of a rectifier or power transistor. Especially, a diode of such performance that it has a short time for which a backward current flows upon transition from a forward bias state to a backward bias state, i.e., that has high-speed recovery characteristics, has been considered to be important for the purpose of reducing noise and preventing surge in power electronics circuits.

As a conventional diode having high-speed recovery characteristics, a Si diode of the pin-junction type has widely been utilized. This diode has such a configuration that sandwiches a high-resistance silicon region between relatively high concentration p-type and n-type silicon regions, in which the diode has a large width of depletion layer, which in turn reduces the junction capacity thereof, thus enabling high-speed operations.

In a pin-type diode, however, a backward current flows for at least a few hundred nanoseconds (as a backward recovery time), so that the time must be reduced by any means. To reduce the backward recovery time, it is effective to reduce the lifetime of a minority carrier in a semiconductor layer. For example, “Semiconductors” (Wiley, N.Y. 1971) by H. F. Wolf and “Semiconductor Devices” (John Wiley & Sons Inc., 1985) by S. M. Sze describe a method for reducing the backward recovery time by reducing the lifetime of a minority carrier specifically by doping gold into the semiconductor layer or by inducing high-speed charged particles to the semiconductor layer. By these methods, a site where gold is doped or charged particles are induced is idealistically limited to a vicinity of a high-resistance silicon region, i.e. to a region where the depletion layer spreads.

The gold doping method, however, suffers from the influence of thermal diffusion, so that gold cannot selectively be doped to only a local site in a semiconductor layer. Furthermore, by the method of applying an electron beam of a variety of charged particles, in principle, it is impossible to selectively apply charged particles to only part of the semiconductor layer. In this case, the diode itself has a degraded breakdown voltage and so suffers from a leakage current. If protons or ions are applied as charged particles, the size is large and so makes the associated apparatus very complicated and expensive, thus increasing the costs of the finished diode.

### BRIEF SUMMARY OF THE INVENTION

It is an object of the present invention to provide a low-cost diode having high-speed backward recovery characteristics.

A diode related to the present invention comprises a Si substrate, an Si film of a first conductivity type laminated on this silicon substrate, and a SiGe film of a second conductivity type laminated on this first conductivity type Si film.

The diode related to the present invention comprises a Si substrate, a Si film of a first conductivity type, a Si film or a high-resistance Si film which has the first conductivity type and also which has a lower impurity doping concentration than that of the former first conductivity type Si film, and a SiGe film of a second conductivity type laminated on this lower impurity doping-concentration Si film or high-resistance Si film.

Preferably, the Ge concentration in this SiGe film of the second conductivity type is more than 2.5 atomic % and less than 15 atomic %, and more preferably, it is set so as to be more than 2.5 atomic % and less than 10 atomic %.

The Ge concentration of the SiGe film should be thus restricted for the following reasons. If the Ge concentration is less than 2.5 atomic %, the SiGe film has almost the same characteristics as the Si film, thus making it difficult to obtain an effect of reducing the backward recovery time. If the Ge concentration of the SiGe film is too large in excess of 10 atomic %, a strain between Si and SiGe becomes too large and increases the leakage current, thus degrading the electrical characteristics (breakdown voltage rectification action) as a diode. It is found that if the Ge concentration of the SiGe film exceeds 15 atomic %, in particular, the rectification action is lost to completely kill the function as a diode. These restrictive values were identified experimentally by the present inventor et al.

The following will describe the actions and effects of the present invention with reference to an example of p-type SiGe/high-resistance Si/n-type Si configuration. The actions and effects described below will appear in a similar manner when this configuration is employed in a low-concentration Si film, when the p-type SiGe film and the n-type Si film are directly joined with each other, and also when the conductivity type is reversed in this configuration.

To reduce the backward recovery time of a diode, it is necessary to decrease the amount of carriers accumulated in the diode. To do so, it is in turn necessary to reduce the lifetime of a minority carrier in the vicinities of the high-resistance Si film, the p-type Si film, the n-type Si film, and the high-resistance Si film.

By adding Ge into Si, it is possible to reduce the lifetime of the minority carrier. Therefore, the lifetime of a carrier in a p-type SiGe film is shortened. Furthermore, since SiGe has a difference in lattice constant from Si, a strain occurs near a region where Si and SiGe are in contact with each other. This strain induces a crystal defect, which in turn shortens the carrier's lifetime. The strain is expected to develop up to the high-resistance Si film and the n-type Si film with which SiGe is in contact, thus suppressing the carrier's lifetime to a low level in the high-resistance Si film and the n-type Si film. That is, the SiGe junction will suppress the carrier's lifetime in the diode as a whole to thereby decrease the amount of charge accumulated, thus realizing high-speed operations.

For convenience, the terms “first conductivity type” and “second conductivity type” are used here to refer to either an n-type or p-type junction state of semiconductors. If an n-type conductivity is defined as the first conductivity type, the p-type conductivity is the second conductivity type, and vice versa.

A diode of the present invention is manufactured by chemical vapor deposition (CVD). By the CVD method, a semiconductor material gas is supplied into a chamber to the full and then a heated substrate is put in the chamber, thus depositing a semiconductor film on the substrate. The CVD method may come in an atmospheric-pressure CVD method, a vacuum CVD method, a plasma-enhanced CVD method, or a photo-assisted CVD method.

### BRIEF DESCRIPTION OF THE SEVERAL VIEWS OF THE DRAWING

FIG. 1 is a schematic block diagram of a configuration of an apparatus used in the manufacture of a diode of the present invention;

FIGS. 2A-2E are a process diagram for showing a process of manufacturing the diode of the present invention;

FIG. 3 is a schematic cross-sectional view for showing a diode related to an embodiment of the present invention;

FIG. 4 is a graph for showing comparison between the diode of the embodiment and a diode of a comparison example in terms of current vs. voltage characteristics at the time of backward recovery; and

FIG. 5 is a graph for showing characteristics of dependency of a backward recovery time on a Ge concentration of a diode having a SiGe film.

### DETAILED DESCRIPTION OF THE INVENTION

The following will describe preferred embodiments of the present invention with reference to the accompanying drawings.

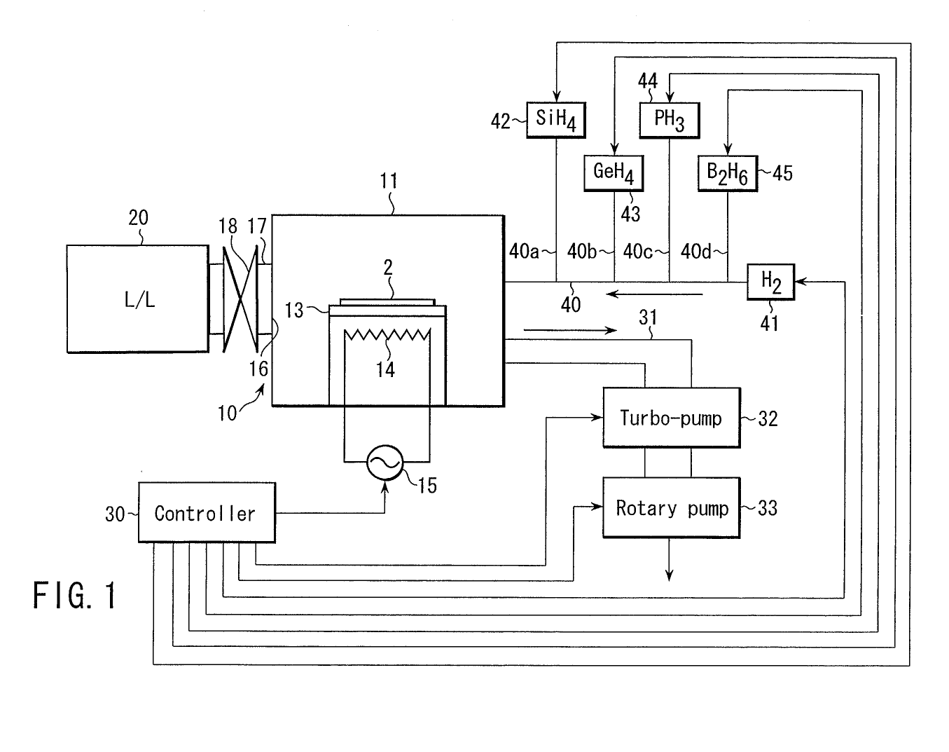

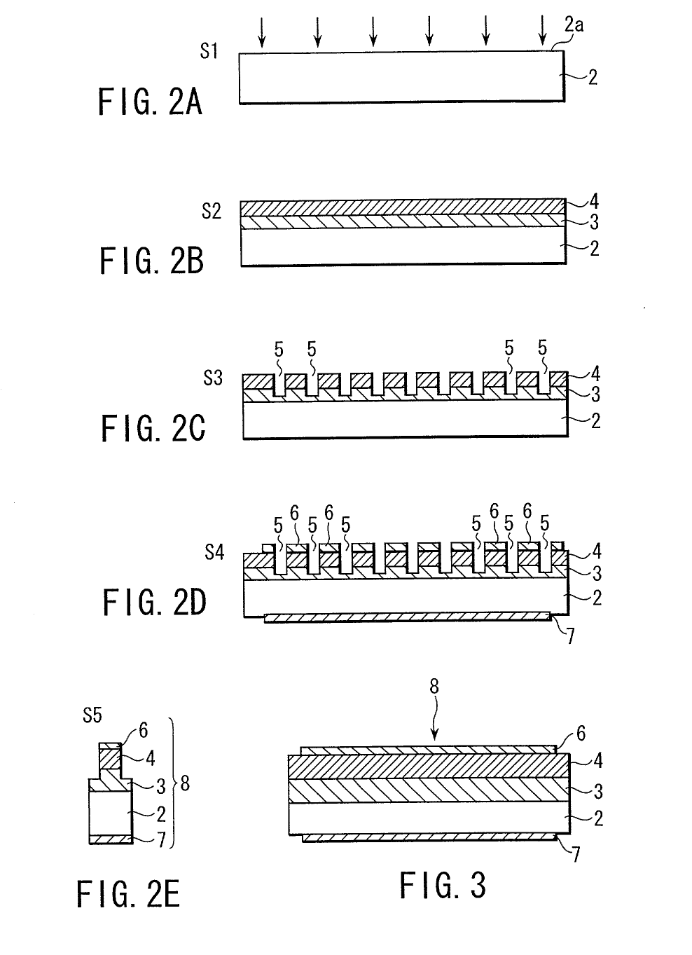

A diode of the present invention is manufactured using a vacuum CVD apparatus shown in FIG. 1. It is actually manufactured in a process comprising a series of steps S1 through S5 shown in FIGS. 2A-2E.

As shown in FIG. 1, in a vacuum CVD apparatus 10, a chamber 11 and a load lock chamber 20 are connected in a communicating manner via a substrate carrying path 17, so that when a gate valve 18 is opened, these two communicate with each other and, when it is closed, they are blocked from each other. A silicon wafer substrate 2, which provides the raw material of a diode, is carried into the chamber 11 of the CVD apparatus through load lock chamber 20 from the outside by a carrying mechanism not shown and carried out of the chamber 11 also through the load lock chamber 20. Note here that an opening 16 in the substrate carrying path 17 is formed on one side of the chamber 11.

An exhaust pipe 31 is opened on the other side of the chamber 11. This exhaust pipe 31 is connected to a turbo-molecular pump 32 and a rotary pump 33 so that the chamber 11 may be highly evacuated. The turbo-molecular pump 32 is disposed along the exhaust pipe 31 on the upstream side (toward the chamber 11) of the rotary pump 33 so that it may completely evacuate the chamber 11 after the rotary pump 33 has roughly evacuated it.

The chamber 11 of the CVD apparatus is provided therein with a stage 13, on which the substrate 2 is to be loaded. The stage 13 integrates a heater 14 which heats the substrate 2.

Five gas supply sources 41, 42, 43, 44, and 45 communicate with the chamber 11 via pipes 40, 40a, 40b, 40c, and 40d. The first gas supply source 41 serves to supply a hydrogen gas (H₂) through the main pipe 40 into the chamber 11. The second gas supply source 42 serves to supply a silane gas (SiH₄) or di-silane gas (Si₂H₆) into the chamber 11 through the branch pipe 40a and the main pipe 40. The third gas supply source 43 serves to supply a germanium gas (GeH₄) into the chamber 11 through the branch pipe 40b and the main pipe 40. The fourth gas supply source 44 serves to supply a phosphine gas (PH₃) into the chamber 11 through the branch pipe 40c and the main pipe 40. The fifth gas supply source 45 serves to supply di-borane gas (B₂H₆) into the chamber 11 through the branch pipe 40d and the main pipe 40.

The gas supply sources 41, 42, 43, 44, and 45 each integrate therein a pressure control valve and a mass-flow controller, which are not shown. This pressure control valve and mass-flow controller are controlled by a controller 30 to highly accurately control the flow amounts of the five kinds of gases in such a manner as to mix them when they meet together in the main pipe 40 and then introduce them into the chamber 11 at a predetermined ratio.

Note here that the controller 30 controls also the operations of a heater power source 15, a power source of the gate valve 18, a power source of the turbo-molecular pump 32, and a power source of the rotary pump 33.

(First Embodiment)

The following will describe a method of manufacturing a diode of the first embodiment with reference to FIGS. 2A-2E.

As shown in FIG. 2A, a surface 2a of the silicon substrate is washed by the RCA method to remove oxygen and carbon from the surface 2a to thereby provide the silicon substrate 2 having a film resistivity value of roughly 0.001 Ω·cm. Note here that the substrate 2 is made of an n-type silicon wafer and has an arsenic (As) doping concentration of 1×10¹⁹/cm³ or so. Furthermore, the RCA method used here is one of the wet-type chemical washing methods using a plurality of kinds of liquid chemicals in combination, as is described obviously in W. Kern and D. A. Puotinen RCA Rev. Vol. 31 (1970) 187. The RCA method employed in this first embodiment specifically comprises the following steps (1) to (12):

(1) a few minutes of washing by use of ultra-pure water;

(2) at least a few minutes of dipping into mixed solution of NH₄OH/H₂O₂/H₂O (NH₄OH:H₂O₂:H₂O=1:2:7) at 75° C.;

(3) a few minutes of washing by use of ultra-pure water;

(4) a few minutes of dipping into 1% hydrofluoric acid solution at room temperature;

(5) a few minutes of washing by use of ultra-pure water;

(6) at least a few minutes of dipping into mixed solution of HCl/H₂O₂/H₂O (HCl:H₂O₂:H₂O=1:2:7) at room temperature;

(7) a few minutes of washing by use of ultra-pure water;

(8) at few minutes of dipping into 1% hydrofluoric acid solution at room temperature;

(9) a few minutes of washing by use of ultra-pure water;

(10) at least a few minutes of dipping into mixed solution of H₂SO₄/H₂O₂/H₂O (H₂SO₄:H₂O₂:H₂O=1:2:7) at room temperature;

(11) a few minutes of washing by use of ultra-pure water; and

(12) drying by spinning.

The Si substrate 2 after being washed was carried into the CVD apparatus 10 and loaded on the stage 13. The gate valve 18 is closed to then use the pumps 32 and 33 in order to evacuate the chamber to its inner pressure of 1×10⁻⁹ Torr. Furthermore, the heater was used to heat the substrate 2 from 800 to 900° C.

When the substrate 2 was being heated, predetermined amounts of gases were supplied from the four respective gas supply sources 41, 42, 44, and 45 into the chamber 11. As a material gas, a mixed gas of di-silane (Si₂H₆) or silane (SiH₄) and phosphine (PH₃) was used. This material gas was diluted with a predetermined flow amount of hydrogen gas. The dilution ratio by use of hydrogen gas was 10%. Since the P-doping concentration for the n-type Si film 3 is determined by a mixture ratio of phosphine with respect to di-silane or silane, to obtain a P-doping concentration of about 5×10¹⁴/cm³, it is necessary to set a partial pressure of PH₃/Si₂H6 (or SiH₄) at 0.01 ppm or so. On the substrate surface 2a was laminated as thick as 20 μm the n-type Si film 3 into which phosphorus (P) was doped at about 5×10¹⁴/cm³ (step S2). Thus obtained n-type Si film 3 has a high resistivity value of 15 Ω·cm or so.

When the substrate 2 was being heated after the evacuation of the chamber 11, predetermined amounts of gases were supplied from the five gas supply sources 41, 42, 43, 44, and 45 into the chamber 11. As the material gas, a mixed gas of di-silane (Si₂H₆) or silane (SiH₄), germanium (GeH₄), and di-borane (B₂H₆) was used. This material gas was diluted with a predetermined flow amount of hydrogen gas. The dilution ratio by hydrogen gas was 10%. Since the B-doping concentration of the p-type Si film 4 is determined by a mixture ratio of di-borane with respect to di-silane or silane, to obtain a B-doping concentration of about 5×10¹⁷/cm³, it is necessary to set a partial pressure of B₂H₆/Si₂H₆ (or SiH₄) at 20 ppm or so. The Ge concentration of SiGe was five atomic %. The substrate temperature during film formation was set at 650° C. or higher. Thus, on the n-type Si film 3 was laminated as much as a thickness of 0.4 μm the p-type SiGe film 4 into which boron (B) was doped at about 5×10¹⁷/cm³ (step S2).

Heating of the substrate 2 by use of the heater was stopped to then evacuate the chamber 11 and open the gate valve 18, thus carrying out the laminate obtained at step S2 from the chamber 11. The surface of this laminate was masked, and wet or dry etching was used to pattern the SiGe film 4 in order to form a plurality of element isolating trenches 5 as shown in FIG. 2C (step S3). The trenches 5 were formed at an equivalent pitch therebetween and, at their respective bottoms, the n-type Si film 3 is exposed.

As shown in FIG. 2D, on the back surface of the substrate 2, aluminum was evaporated to thereby form a cathode electrode 7. Furthermore, aluminum was evaporated on the p-type SiGe film 4 to thereby form an anode electrode 6 (step S4).

As shown in FIG. 2E, the laminate obtained at step S4 was divided into chips by cutting it along the trenches 5 using a dicing machine, the surfaces of which chips were then covered by a protective film (not shown) except on both electrodes 6 and 7, thus obtaining a finished diode 8 (step S5). The chip area of the diode of the first embodiment was 25 mm².

A rough cross-sectional view of this fabricated diode is shown in FIG. 3. A diode 8 of the first embodiment has such a configuration that the Si film 3, the SiGe film 4, and the anode electrode 6 are sequentially laminated on the n-type Si substrate 2, and the cathode electrode 7 is provided on the back surface of the Si substrate 2.

(Control)

As a comparison example, such a diode was made that has almost the same configuration as that of the first embodiment with an exception that a p-type Si film is formed in place of the p-type SiGe film 2. The p-type Si film was formed under such conditions that as the material gas a mixed gas of di-silane (Si₂H₆) or silane (SiH₄) and di-borane (B₂H₆) was used. Since the B-doping concentration of the p-type Si film 2 is determined by a mixture ratio of di-borane with respect to di-silane or silane, to obtain a B-doping concentration of about 5×10¹⁷/cm³, it is necessary to set a partial pressure of B₂H₆/Si₂H₆ (or SiH₄) at 20 ppm or so. The substrate temperature during film formation was set at 650° C. or higher. The chip area of the diode of this comparison example was 25 mm².

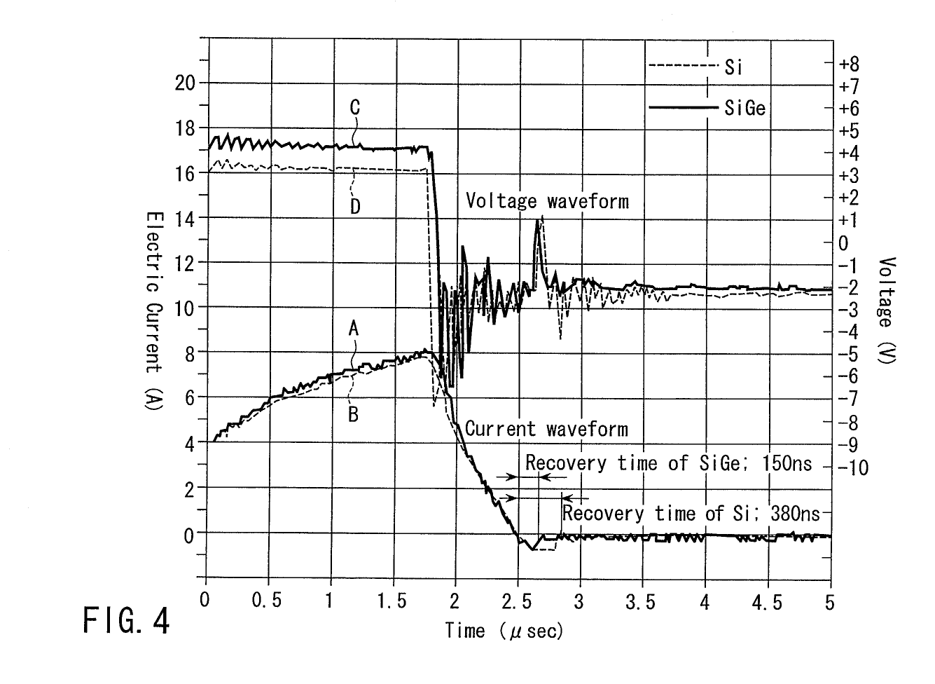

FIG. 4 is a graph in which the abscissa represents time (μs) and the right and left ordinate axes represent voltage (V) and current (A), respectively, to compare the recovery characteristics of the SiGe-film diode with those of the Si-film diode. In the graph, a characteristic curve A shows a current waveform of the SiGe-film diode, a characteristic curve B shows a current waveform of the Si-film diode, a characteristic curve C shows a voltage waveform of the SiGe-film diode, and a characteristic curve D shows a voltage waveform of the Si-film diode.

In the measurement, a forward current of 4 A was made to flow in the initial state and, at a moment when a bias voltage applied across the diode was reversed, a change in the diode current was determined. The backward recovery time refers to a time which elapses from the moment when the current value along the current waveform once exceeds a zero level to a moment when it returns to zero again. As can be seen from characteristic curve A in the graph, the backward recovery time of the SiGe-film diode (first embodiment) was about 150 ns. The backward recovery time of the Si-film diode (comparison example), on the other hand, was about 380 ns as shown by characteristic curve B in the graph. These measurement results made it clear that a diode using an SiGe film can reduce its backward recovery time by 40% as compared to a prior art diode.

(Second Embodiment)

The following will describe a method for manufacturing a diode of the second embodiment along FIGS. 2A-2E.

The surface 2a of a silicon substrate was washed by the RCA method as mentioned above and then oxygen and carbon were removed therefrom to thereby provide a silicon substrate 2 having a film resistivity value of 0.001 Ω·cm or so (step S1). Note here that the substrate 2 is made of a silicon wafer, having an arsenic (As) doping concentration of 1×10¹⁹/cm³ or so.

The Si substrate 2 after being washed was carried into the CVD apparatus 10 and loaded on the stage 13. The gate valve 18 is closed to then use the pumps 32 and 33 in order to evacuate the chamber to its inner pressure of 1×10⁻⁹ Torr. Furthermore, the heater was used to heat the substrate 2 to 800-900° C.

When the substrate 2 was being heated, predetermined amounts of gases were supplied from the four respective gas supply sources 41, 42, 44, and 45 into the chamber 11. As a material gas, a mixed gas of di-silane (Si₂H₆) or silane (SiH₄) and phosphine (PH₃) was used. This material gas was diluted with a predetermined flow rate of hydrogen gas. The dilution ratio by use of hydrogen gas was 10%. Since the P-doping concentration for the n-type Si film 3 is determined by a mixture ratio of phosphine with respect to di-silane or silane, to obtain a P-doping concentration of about 5×10¹⁴/cm³, it is necessary to set a partial pressure of PH₃/Si₂H₆ (or SiH₄) at 0.01 ppm or so. On the substrate surface 2a was laminated as thick as 20 μm the n-type Si film 3 into which phosphorus (P) was doped at about 5×10¹⁴/cm³, (step S2). Thus obtained n-type Si film 3 has a high resistance value of 20 Ω·cm or so.

When the substrate 2 was being heated after the evacuation of the chamber 11, predetermined amounts of gases were supplied from the five gas supply sources 41, 42, 43, 44, and 45 into the chamber 11. As the material gas, a mixed gas of di-silane (Si₂H₆) or silane (SiH₄), germanium (GeH₄), and di-borane (B₂H₆) was used. This material gas was diluted with a predetermined flow rate of hydrogen gas. The dilution ratio by hydrogen gas was 10%. In manufacture, the Ge concentration of the SiGe film was changed in a range of 0 to 15 atomic %. The substrate temperature during film formation was set at 650° C. or higher. Thus, on the n-type Si film 3 was laminated as much as a thickness of 0.4 μm of the p-type SiGe film 4 into which boron (B) was doped at about 5×10¹⁷/cm³ (step S2).

Heating of the substrate 2 by use of the heater was stopped to then evacuate the chamber 11 and open the gate valve 18, and the laminate obtained at step S2 was then carried out of the chamber 11. The surface of this laminate was masked, and a wet or dry etching was used to pattern the SiGe film 4 in order to form a plurality of element isolating trenches 5 as shown in FIG. 2C (step S3). The trenches 5 were formed at an equivalent pitch therebetween and, at their respective bottoms, the n-type Si film 3 is exposed.

As shown in FIG. 2D, on the back surface of the substrate 2, aluminum was evaporated to thereby form a cathode electrode 7. Furthermore, aluminum was evaporated on the p-type SiGe film 4 to thereby form an anode electrode 6 (step S4).

As shown in FIG. 2E, the laminate obtained at step S4 was divided into chips by cutting it along the trenches 5 using a dicing machine, the surfaces of which chips were then covered by a protective film (not shown) except on both electrodes 6 and 7, thus obtaining a finished diode 8 (step S5). The chip area of the diode of the second embodiment was 25 mm².

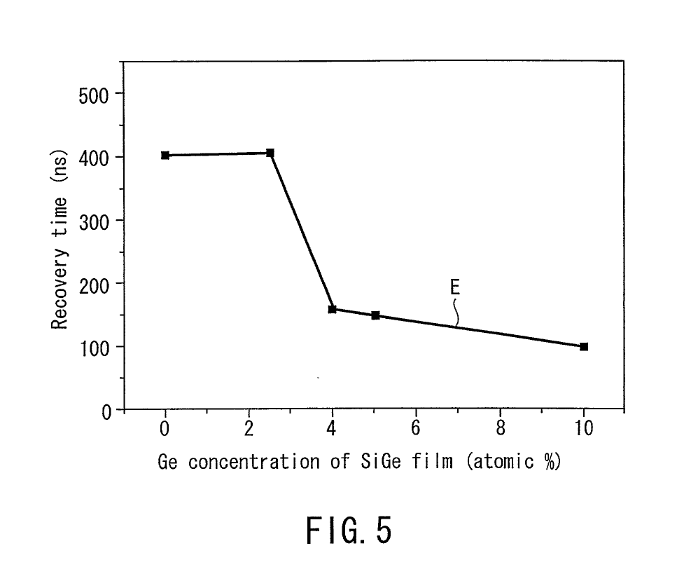

FIG. 5 is a characteristic diagram for showing the measure dependency of the backward recovery time of various SiGe-film diodes on the Ge concentration in which the abscissa represents the Ge concentration (atomic %) in the SiGe film and the ordinate represents the backward recovery time (ns) of the various SiGe-film diodes. In the graph, characteristic curve E connects real measurement plots of the backward recovery time. As can be seen from the graph, the SiGe film having a Ge concentration of 2.5 atomic % or less exhibited little effect of reducing the backward recovery time (about 400 ns), whereas the SiGe film with a Ge concentration more than 2.5 atomic % and not more than 10 atomic % exhibited a significant reduction in the backward recovery time of about 100-150 ns.

The SiGe film with a Ge concentration of 15 atomic % had a reverse-biased leakage current generated therein and did not function as a diode at all. These made it clear that to reduce the backward recovery time, it is necessary to set the Ge concentration of the SiGe film at a value more than 2.5 atomic % and less than 15 atomic % and, more preferably, at a value more than 2.5 atomic % and not more than 10 atomic %.

A rough cross-sectional view of thus manufactured diode of the second embodiment is shown in FIG. 3.

According to the present invention, it is possible to significantly reduce the backward recovery time of a diode as compared to a prior art product. Especially by setting the Ge concentration of the SiGe film at a value in the optimal range, the backward recovery time can be reduced by 40% as compared to the prior art product.

Furthermore, a diode of the present invention is less expensive than a prior art product manufactured by the gold doping method or the charged-particle inducing method.

What is claimed is:

1. A diode comprising:
a Si substrate,
a Si film of a first conductivity type laminated on said Si substrate, and
a SiGe film of a second conductivity type laminated on said first conductivity type Si film

2. A diode according to claim 1, wherein a Ge concentration in said second conductivity type SiGe film is set so as to be more than 2.5 atomic % and less than 15 atomic %.

3. A diode according to claim 1, wherein a Ge concentration in said second conductivity type SiGe film is set so as to be more than 2.5 atomic % and not more than 10 atomic %.

4. A diode according to claim 1, wherein said Si substrate is of the first conductivity type.

5. A diode comprising:
a Si substrate,
a Si film of a first conductivity type,
a Si film or high-resistivity Si film which is of said first conductivity type and which has an impurity-doping concentration lower than said first conductivity type Si film, and
a SiGe film of a second conductivity type which is laminated on said Si film or high-resistivity Si film having said lower impurity-doping concentration.

6. A diode according to claim 5, wherein a Ge concentration in said second conductivity type SiGe film is set so as to be more than 2.5 atomic % and less than 15 atomic %.

7. A diode according to claim 5, wherein a Ge concentration in said second conductivity type SiGe film is set so as to be more than 2.5 atomic % and not more than 10 atomic %.

8. A diode according to claim 5, wherein said Si substrate is of the first conductivity type.
